(19) United States
(12) Patent Application Publication
(10) Pub. No.: US 2026/0136579 A1
(43) Pub. Date: May 14, 2026

(54) TRENCHED TRANSISTOR WITH GROOVED GATE

(71) Applicants: Kyocera Corporation, Kyoto (JP); Leland Stanford University, Stanford, CA (US)

(72) Inventors: Hayao Kasai, Tsukuba (JP); Xinyi Wen, Stanford, CA (US); Srabanti Chowdhury, Stanford, CA (US)

(73) Assignees: Kyocera Corporation, Kyoto (JP); Leland Stanford University, Stanford, CA (US)

(21) Appl. No.: 18/989,435

(22) Filed: Dec. 20, 2024

Related U.S. Application Data
(60) Provisional application No. 63/719,538, filed on Nov. 12, 2024.

(51) Int. Cl. H10D 30/47; H10D 30/01; H10D 30/67; H10D 62/85

(52) U.S. Cl. CPC H10D 30/476; H10D 30/015; H10D 30/477; H10D 30/6735; H10D 62/8503

(57) ABSTRACT

Aspects and features of this disclosure include a normally-off trenched transistor, which may include a wrap-around gate structure on a GaN substrate. The transistor includes a substrate and a p-n structure on the substrate. The p-n structure defines a trench. The transistor also includes a channel covering the trench on at least a portion of the p-n structure. Periodically-spaced grooves penetrate at least a portion of the p-n structure. The gate, on an insulating layer, incorporates the periodically-spaced grooves. An example of a vertical device that can include aspects and features of this disclosure is the current aperture vertical electron transistor (CAVET). An example of a lateral device that can include aspects and features of this disclosure is the high-electron-mobility transistor (HEMT).

### CROSS-REFERENCE TO RELATED APPLICATION

This claims priority to U.S. Provisional Patent Application 63/719,538, filed Nov. 12, 2024, the entire disclosure of which is incorporated herein by reference.

### TECHNICAL FIELD

This disclosure generally relates to trenched transistors, in which current flows through a channel that is, to at least some extent, covering a trench formed in the transistor's structure. Such a transistor may be arranged vertically or laterally. More specifically, but not by way of limitation, this disclosure relates to the gate structure in trenched transistors.

### BACKGROUND

Gallium nitride (GaN) trenched transistors can perform well at high power ranges (>10 kW). Examples of GaN trenched devices include the current aperture vertical electron transistor (CAVET) and the high-electron-mobility transistor (HEMT). These devices can include a “gate all around” (GAA), also called a “wrap-around gate” (WG), to improve the level of control imposed by the gate's electric field on the channel. Among GaN vertical devices, the CAVET has demonstrated fast switching capability at high frequencies, even up to 10 MHz. Both CAVETs and HEMTs may exhibit normally-on behavior.

### SUMMARY

Certain aspects and features of the present disclosure relate to a trenched transistor with a grooved gate. For example, a trenched transistor includes a substrate, and a p-n structure on the substrate. The p-n structure defines a trench. The trenched transistor further includes channel material on at least a portion of the p-n structure opposite the substrate, and the channel material covers the trench. The trenched transistor also includes periodically-spaced grooves defined substantially within the trench and penetrating at least a portion of the p-n structure. The trenched transistor additionally includes an insulating layer on the channel material and on at least some internal surfaces of the periodically-spaced grooves. A gate on the insulating layer of the trenched transistor incorporates the periodically-spaced grooves.

Certain aspects and features relate to a CAVET with a grooved gate. For example, a CAVET includes a GaN substrate, and a GaN p-n structure on the substrate, where the GaN p-n structure defines a trench. The CAVET further includes periodically-spaced grooves substantially within the trench and extending into the GaN p-n structure. The CAVET also includes a gate on the GaN p-n structure so as to incorporate the periodically-spaced grooves.

Certain aspects and features related to a method of making a vertical transistor. For example, a method includes etching a trench in a p-n structure, and regrowing channel material on the p-n structure to cover internal surfaces of the trench. A method further includes depositing a source electrode on the p-n structure and the channel material. The method also includes etching periodic grooves substantially within the trench and extending into the p-n structure, and depositing a gate on at least some internal surfaces of the periodic grooves to form a grooved gate.

### BRIEF DESCRIPTION OF THE FIGURES

FIG. 1 is a cutaway view of a vertical transistor device with a grooved gate according to some aspects of the present disclosure.

FIG. 2 is a diagram illustrating a portion of the grooved structure of the vertical transistor device illustrated in FIG. 1.

FIG. 3 is a cross-sectional view of a vertical transistor with a grooved gate according to additional aspects of the present disclosure.

FIG. 4 is a cut-away view of the vertical transistor with a grooved gate shown in FIG. 3 according to some aspects of the present disclosure.

FIG. 5A and FIG. 5B schematically illustrate a portion of the vertical transistor illustrated in FIG. 3 and FIG. 4 as well as the gate's effect on the channel of a vertical transistor with a grooved gate according to some aspects of the present disclosure.

FIG. 6 is a graph illustrating the effect of groove spacing in a vertical transistor with a grooved gate according to some aspects of the present disclosure.

FIG. 7A through FIG. 7E are graphical views of a process for making a vertical transistor with a grooved gate according to some aspects of the present disclosure.

FIG. 8 is a graph illustrating the transfer characteristics of a vertical transistor with a grooved gate according to some aspects of the present disclosure.

FIG. 9 is a graph illustrating the output characteristics of a vertical transistor with a grooved gate according to some aspects of the present disclosure.

FIG. 10 is a cutaway top-down view of a large-area vertical transistor with a multi-finger grooved gate according to some aspects of the present disclosure.

FIG. 11 is a graph illustrating the transfer characteristics of a large-area vertical transistor with a grooved gate according to some aspects of the present disclosure.

FIG. 12 is a graph illustrating the output characteristics of a large-area vertical transistor with a grooved gate according to some aspects of the present disclosure.

FIG. 13 is a cross-sectional view of a lateral transistor with a grooved gate according to additional aspects of the present disclosure.

FIG. 14 is a graph illustrating the transfer characteristics of a lateral transistor with a grooved gate according to additional aspects of the present disclosure.

FIG. 15 is a graph illustrating the output characteristics of a lateral transistor with a grooved gate according to additional aspects of the present disclosure.

### DETAILED DESCRIPTION

GaN vertical transistors such as the CAVET can provide fast switching capability at high frequencies, even up to 10 MHz, since they incorporate a two-dimensional electron gas (2DEG) channel. However, the normally-on behavior of the 2DEG channel increases the complexity of the corresponding gate driver design and poses difficulty for fail-safe operations in power electronics applications. Various strategies can be used to shift the threshold voltage (VTH or V_{TH}) toward the positive direction, but these may produce a device with a relatively small VTH and a low gate swing voltage. To prevent the device from accidentally turning on and ensure compatibility with gate driver designs for silicon technology, a relatively high VTH value as well as a large gate swing voltage can be desirable for vertical transistors, especially for certain use cases where electromagnetic interference is high. Further, a trade-off may exist between the 2DEG carrier density (Ns) and VTH, leading to significant degradation in Ns (e.g., to below 3×10¹² cm⁻²) for large VTH (e.g., VTH>3V). VTH instability may also occur in p-GaN gate devices, and the gate swing voltage may be constrained. Thus, vertical transistors have been unsuitable or for use for many power electronics applications.

Certain aspects of this disclosure relate to a normally-off, trenched transistor with a grooved gate structure. Some aspects relate to a vertical GaN trench CAVET with a wrap-around gate structure (WG-CAVET) on a GaN substrate. The transistor can provide a relatively large VTH (e.g., 6.5 V) and a relatively high gate swing voltage (e.g., at least 40 V in some devices) to prevent unintended turn-on and ensure compatibility with many existing gate driver designs. In some examples, a metal-insulator-semiconductor (MIS) gate that wraps around the 2DEG channel three-dimensionally includes a periodic groove structure, which enhances the gate controllability and mitigates dispersion by acting as a field plate. The device can achieve a high current density and a low specific on-resistance, with a high breakdown voltage. Furthermore, the WG-CAVET can be scaled to a large-area device using a multi-gate-finger structure to provide high current operations. Some aspects of this disclosure relate to a normally-off, lateral transistor, such as an HEMT with a grooved gate structure.

In some examples, a trenched transistor includes a substrate and a p-n structure on the substrate. The p-n structure defines a trench. The trenched transistor also includes channel material covering the trench on at least a portion of the p-n structure opposite the substrate. Periodically-spaced grooves penetrating at least a portion of the p-n structure are defined substantially within the trench. The trenched transistor includes an insulating layer on the channel material and on at least some internal surfaces of the periodically-spaced grooves. A gate on the insulating layer incorporates the grooved structure.

In some examples, a CAVET includes a substrate and a p-n structure on the substrate. The p-n structure defines a trench. Channel material on at least a portion of the p-n structure opposite the substrate covers the trench. Periodically-spaced grooves are defined substantially within the trench. The periodically-spaced grooves penetrate the channel material and at least a portion of the p-n structure. An insulating layer is disposed on the channel material and on at least some internal services of the periodically-spaced grooves. A gate on the insulating layer incorporates the periodically-spaced grooves.

In some examples, a vertical transistor is made by etching a trench in a p-n structure and regrowing channel material on the p-n structure to cover internal surfaces of the trench. A source electrode is deposited on the p-n structure and the channel material and periodic grooves are etched substantially within the trench and extending into the p-n structure. A gate is deposited to cover at least some internal surfaces of the periodic grooves.

A large-area vertical transistor as described herein may include a gate with multiple fingers substantially coextensive with and wrapping around the source electrode. The term “substantially” in this context, in one example, means that at least a majority of each gate electrode's finger is coextensive with the source electrode's. Some or all of the fingers may incorporate the periodically-spaced grooves. The p-n structure may include p-GaN and n-GaN. A stop layer may be placed between the channel and the p-n structure.

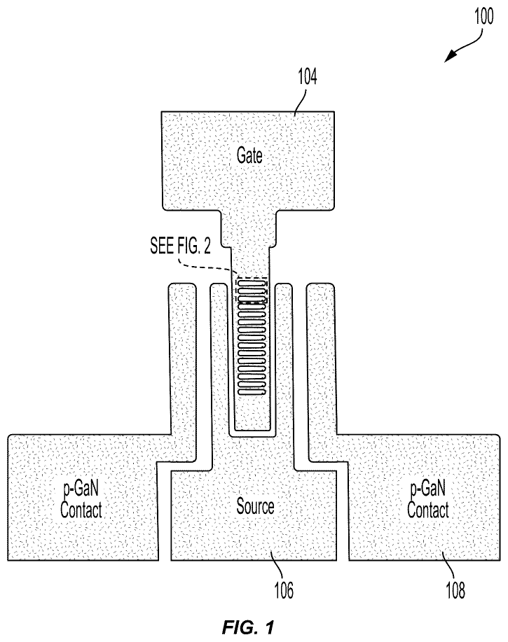

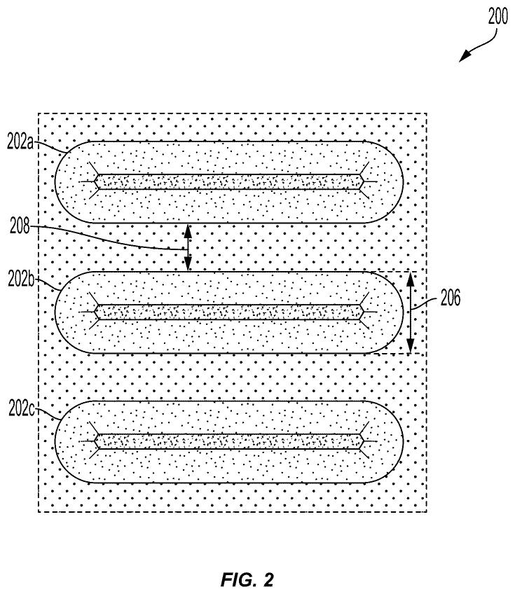

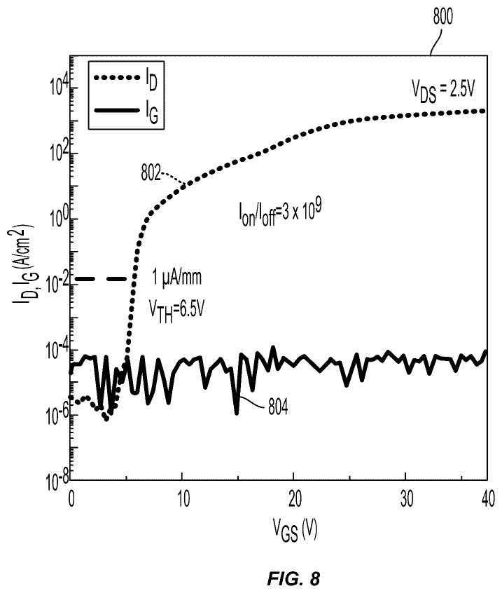

FIG. 1 is a cutaway view of a vertical transistor device with a grooved gate according to some aspects of the present disclosure. FIG. 1 shows an example WG-CAVET 100 (transistor 100) from the top according to embodiments described herein. Transistor 100 includes a single gate finger 102, forming a portion of gate 104. However, such a transistor can be scaled to have many gate fingers, as will be described below with respect to FIG. 8. Visible in this top view of transistor 100 is also the source 106 and the p-GaN contact 108, with two different portions of the p-GaN contact visible in this view. Groove structure 112 includes multiple, periodically-spaced grooves, which are illustrated in further detail in FIG. 2, discussed below. Current in transistor 100 as shown in the figure flows from top to bottom. The number of grooves in a device will vary depending on the size of the device and the spacing and size of the grooves. As an example, a 100-micron wide device might include 10-50 grooves.

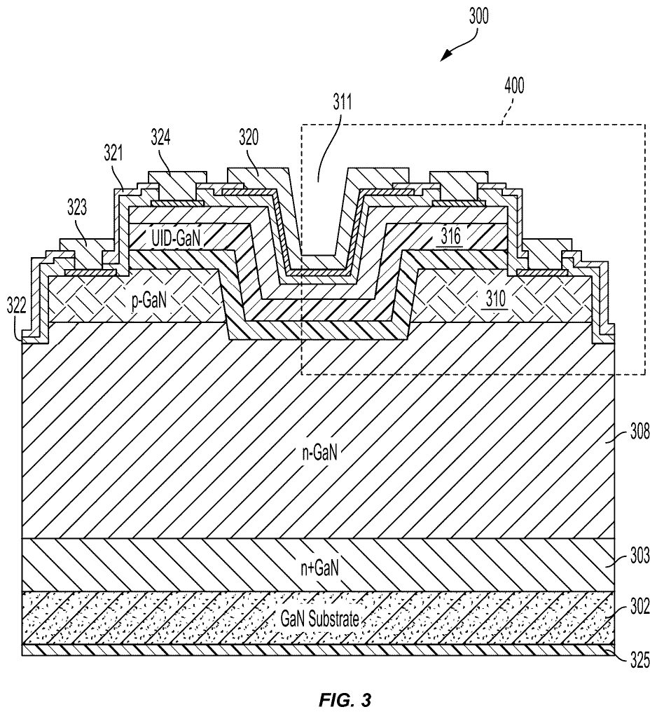

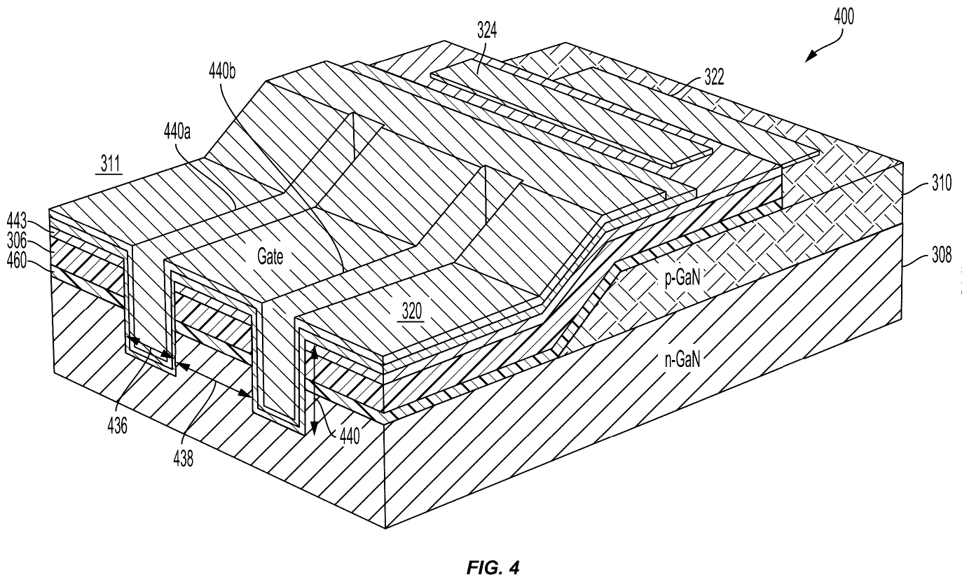

FIG. 2 is a diagram illustrating a portion of the grooved structure of the vertical transistor device illustrated in FIG. 1. FIG. 2 shows a portion 200 of periodic groove structure 112. Portion 200 of periodic groove structure 112 includes grooves 202a-c. In this example, the grooves 202a-c each have a width 206 of 2.4 μm with a space 208 between grooves of 1.5 μm. As an example, a spacing from 0.1 μm to 10 μm may be used. As another example, the grooves may be spaced apart by from 0.5 μm to 5 μm. Normally-off behavior of WG-CAVET 100, along with relatively high VTH and relatively high gate swing voltage can be achieved with a variety of groove spacings and dimensions. A narrower groove spacing results in a lower electric field at the groove corners and on the top of the grooves. Additional discussion regarding dimensions of the grooves is included in the description of FIG. 4. The groove structure enhances the gate controllability and mitigates dispersion by acting as a field plate. The top of the gate finger in this example is a barrier layer, as will be discussed further below with respect to FIG. 3.

FIG. 3 is a cross-sectional view of an example vertical transistor 300 with a grooved gate according to additional aspects of the present disclosure. A cut-away portion 400 of transistor 300 is shown in FIG. 4 and discussed below. The gate may also be referred to herein as a gate electrode or gate metal. In FIG. 3, transistor 300 is built on GaN substrate 302, and may include a thin (˜2 μm) n+GaN layer 303. When metalorganic chemical vapor deposition (MOCVD) is used to grow GaN epitaxial layers on GaN substrates, impurities can be deposited on the surface of the substrate, making the substrate highly resistive. Doping the surface with Si or Ge to form an n+ layer mitigates this effect. Transistor 300 features regrown (epitaxially grown) layers including an unintentionally doped (UID) GaN layer 306 of channel material. These layers are grown on top of the vertical GaN p-n structure including n-GaN layer 308 and p-GaN layer 310. The channel material, UID-GaN layer 316, covers trench 311 and a portion of the p-n structure opposite the substrate 302. Transistor 300 includes a metal-insulator-semiconductor (MIS) gate electrode 320 that wraps around the channel three-dimensionally.

Staying with FIG. 3, transistor 300 features an SiO₂ passivation layer 321 deposited on an insulating layer 322, and a p-GaN contact 323, which provides a fixed-potential electrode coupled with the surface of p-GaN layer 310. The insulating layer can be deposited before gate electrode deposition and the passivation layer 321 can be deposited after gate electrode deposition by plasma enhanced chemical vapor deposition (PECVD). Any of various dielectrics can be used to form the insulating layer. Examples include, but are not limited to Al₂O₃, SiO₂, AlON, HfO₂, SIN, SiON, or hBN (hexagonal). Transistor 300 also includes source electrode 324 and a drain electrode 325. In an example, the electrodes are composed of Ti/Au and the pads visible underneath are composed of Ti/Al/Ni/Au or Ni/Au. In a finished device the drain electrode is fixed to the bottom of GaN substrate 302. The periodic groove structure (directly visible in FIG. 4) is formed in the trench region, which is shown with more detail in FIG. 4. The additional layers visible in FIG. 3 are also discussed in more detail below with reference to FIG. 4.

FIG. 4 is a cut-away portion 400 of the example vertical transistor shown in FIG. 3 according to some aspects of the present disclosure. Portions of the passivation and insulating layers are omitted for clarity. Like reference numbers refer to like structures. In the example of FIG. 4, two grooves of the periodic groove structure are visible, grooves 440a-b, which are oriented to be substantially perpendicular to a direction of the trench 311. The term “substantially” in this context may mean that a center line of each groove is perpendicular to a center line of the trench to within five degrees, or within typical manufacturing tolerances. The grooves are also sized to be substantially within the trench 311. The term “substantially” in this context means that from a majority to the entire groove is within the trench, including sidewalls of the trench.

Continuing with FIG. 4, in addition to the width 436 and the spacing 438 of the grooves, the depth 442 of the grooves is also shown. In embodiments, the grooves have a depth 440 ranging from 5 μm to 68 nm. In the example of FIG. 4, the minimum groove depth is the thickness of the barrier layer 443 plus approximately 50 nm so that the grooves extend into the drift layer, penetrating the channel material and at least a portion of the p-n structure, visibly extending into n-GaN layer 308. The maximum depth corresponds to the thickness of the drift layer. A deeper groove results in lower leakage current and a higher electric field at the corners of the grooves. In this example, the barrier layer is an alloyed AlGaN composition, which can be expressed as AlₓGa₍₁₋ₓ₎N, where x can range from 0.1 to 1.

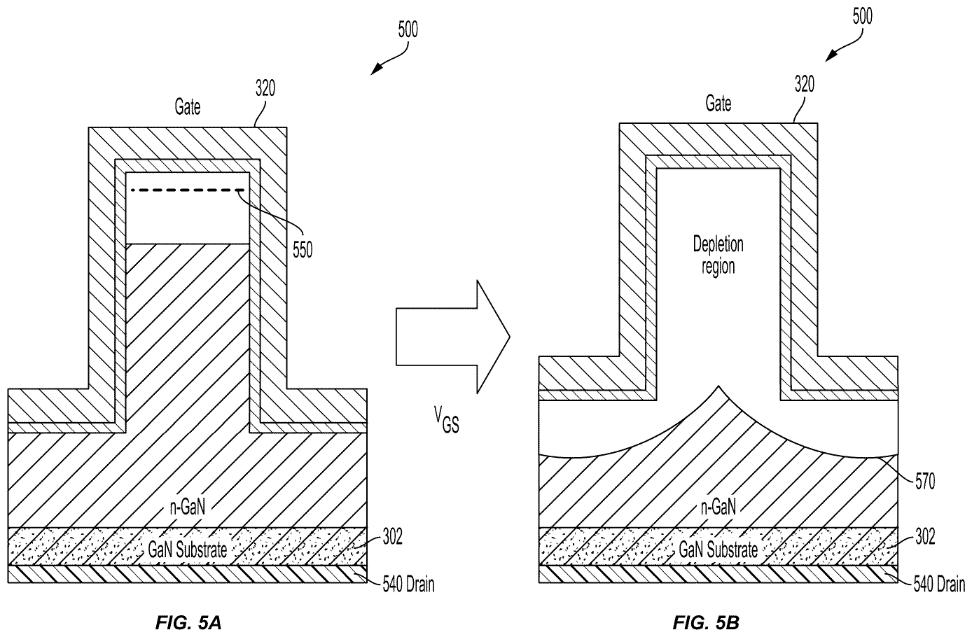

Staying with FIG. 4, transistor 300 includes a magnesium stop layer (MSL) 460. Barrier layer 443 is configured to act with the channel layer 306 to form a polarization-induced 2DEG at the interface between the two, on the UID-GaN side. The 2DEG channel is illustrated in FIG. 5, discussed below. The 2DEG channel forms in the UID-GaN channel material adjacent to a boundary between the UID-GaN channel material and the barrier layer, and occupies the UID-GaN side of the boundary. MSL 460 acts as a protective layer between the p-GaN and the AlₓGa₍₁₋ₓ₎N/UID-GaN layers to inhibit magnesium (Mg) out-diffusion.

The design shown in FIG. 3 and FIG. 4 improves the gate controllability, shifting VTH toward the positive direction, in an amount that can be controlled by the groove dimensions. As the spacing of gate grooves decreases, the depletion regions along the groove sidewalls during operation of the device start to overlap, effectively pinching off the channel in the off state. In examples, groove width can be from 1.8 μm to 3.0 μm. Generally, the beneficial effects of the grooves are greatest with smaller widths, however, the insulating and passivation layers (in one example about 100 nm thick) and gate metal 320 (in one example about 230 nm thick) should fill the grooves, which limits the groove width, though a minimum width will vary depending on processing variables, device size, etc.

FIGS. 5A and 5B illustrate a portion 500 of the vertical transistor 300 illustrated in FIG. 3 and FIG. 4 as well as the gate's effect on the channel of the vertical transistor shown in FIG. 3 and FIG. 4, according to some aspects of the present disclosure. Both views include drain electrode 540. These views omit n+GaN layer 303, as this layer would be very thin compared to the rest of the device in this view. FIG. 5A shows the transistor as gate voltage is applied to the contacts and begins to increase. The grooves 440a-b are shown with the gate portion of transistor protruding upwards in between the grooves. The 2DEG channel 550 is formed in the channel material near the barrier layer as described above. In the view of FIG. 5B, depletion region 570 is formed as a result of decreased gate voltage being applied. As groove spacing in a device decreases, the depletion regions begin to overlap, ultimately pinching off the 2DEG channel.

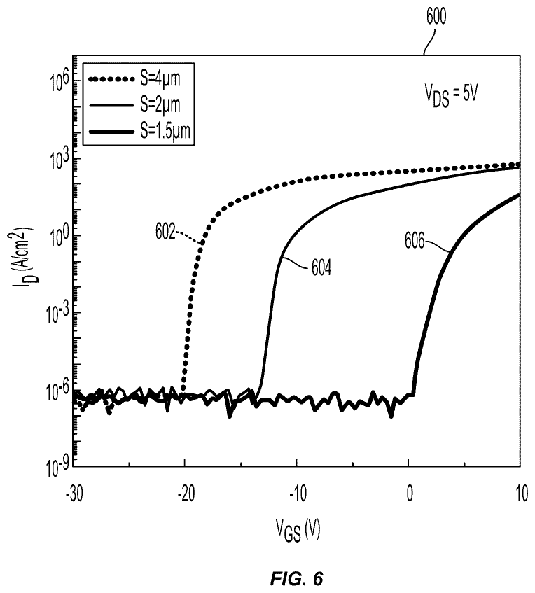

FIG. 6 is a graph 600 illustrating the effect of groove spacing(S) in a vertical transistor with a grooved gate according to some aspects of the present disclosure. Graph 600 shows the effect as drain current Ip with respect to gate voltage V_{GS}. Curve 602 is for a groove spacing of 4 μm, curve 604 is for a groove spacing of 2 μm, and curve 606 is for a groove spacing of 1.5 μm.

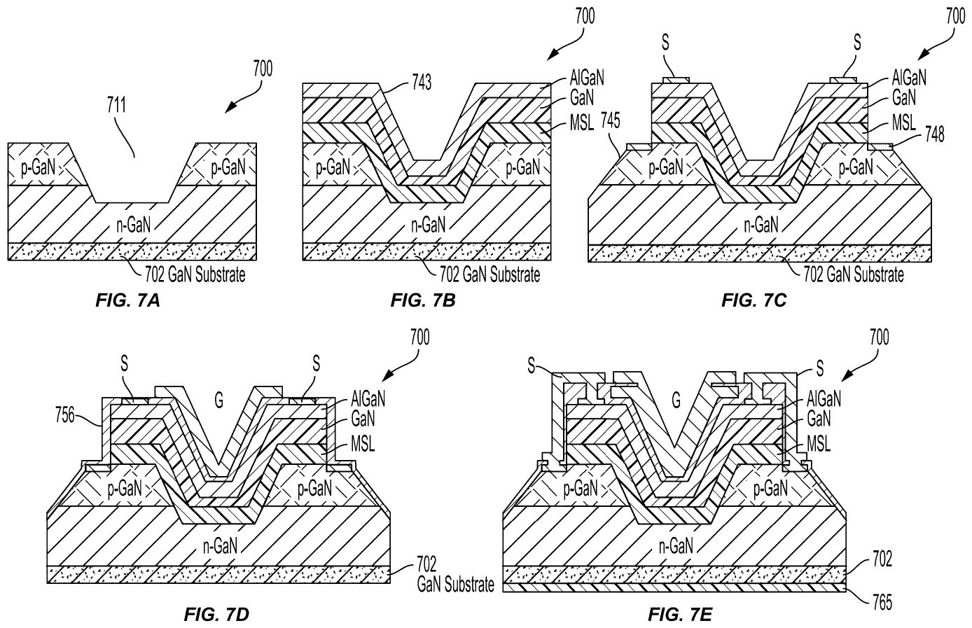

FIGS. 7A through 7E provide graphical illustrations of a process 700 for making a transistor (WG-CAVET) with a grooved gate according to some aspects of the present disclosure. A device can be produced using an all-metal-organic chemical vapor deposition (MOCVD) process, starting with an epitaxial p-n structure including 5 μm n-GaN (Si: 1.7×10¹⁶ cm⁻³) and 450 nm p-GaN (Mg: 1×10¹⁹ cm⁻³). FIG. 7A shows trench 711 etched in the p-n structure. FIG. 7B illustrates regrown GaN channel material along with a regrown MSL and a regrown barrier layer 743. The regrowth can produce 100 nm of low-temperature GaN to prevent Mg out-diffusion, 140 nm of UID-GaN, and 18 nm of AlₓGa₍₁₋ₓ₎N.

Continuing with FIG. 7C, this view illustrates optional device edge-termination with a beveled edge. In some examples, this beveled edge 745 has a 5-degree angle relative to the horizontal, with the angle being exaggerated in the figure for clarity. Also, in FIG. 7C of process 700, the p-GaN material has been activated with rapid thermal annealing and the source electrode (S) has been deposited (e.g., a Ti/Al/Ni/Au source metal), after which the device is put through post-annealing to form ohmic contacts. An ohmic contact 748 is also formed on the exposed p-GaN surface using Ni/Au. A 2 μm deep periodic groove structure (not visible here) as previously described is etched using inductively coupled plasma-reactive ion etching (ICP-RIE). In the view of FIG. 7D, atomic layer deposition of a 100 nm dielectric gate insulator layer 756 is carried out. Gate metallization has been carried out in view of FIG. 7E, for example, to form an Ni/Au gate electrode. A passivation layer (not in the device shown) may be deposited after the gate metallization. Also, a Ti/Au drain electrode 765 is formed on the bottom of substrate 702 in FIG. 7E.

FIG. 8 is a graph 800 illustrating the transfer characteristics of a vertical transistor with a grooved gate according to some aspects of the present disclosure. Curve 802 shows drain current Ip and curve 804 shows gate current IG, both with respect to gate voltage Vas.

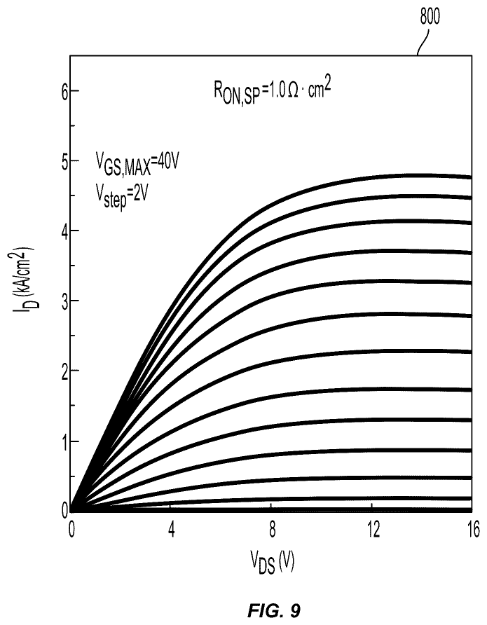

FIG. 9 is a graph 900 illustrating the output characteristics of a vertical transistor with a grooved gate according to some aspects of the present disclosure. The curves represent 2 V increments, showing drain current Ip with respect to drain source voltage V_{DS}. The 40 V gate voltage swing is a limit of the equipment being used for testing, and is not necessarily a limit of the device. Devices in some examples may be produced with gate swing voltages from 5 V to 80 V. In other examples, devices may have gate swing voltages that range from 20 V to 80 V, or from 40 V to 80 V.

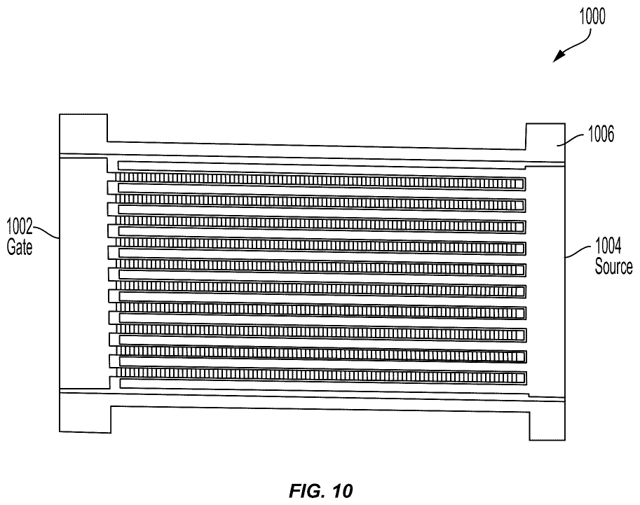

FIG. 10 is a cutaway top-down view of a vertical transistor 1000 with a multi-finger grooved gate according to some aspects of the present disclosure. The use of multiple gate fingers and multiple source fingers creates a large area WG-CAVET. In this example, gate 1002 includes ten fingers and source 1004 includes eleven fingers. The grooves are visible (without detail) in the gate fingers. p-GaN contact 1006 is also visible. The number of grooves per gate finger will depend on the width of the device and the spacing and size of the grooves. Gate width can vary between tens of microns and several millimeters based on the width of the device. As a result, a large area CAVET in the examples illustrated herein may have 10 to 5000 grooves per finger.

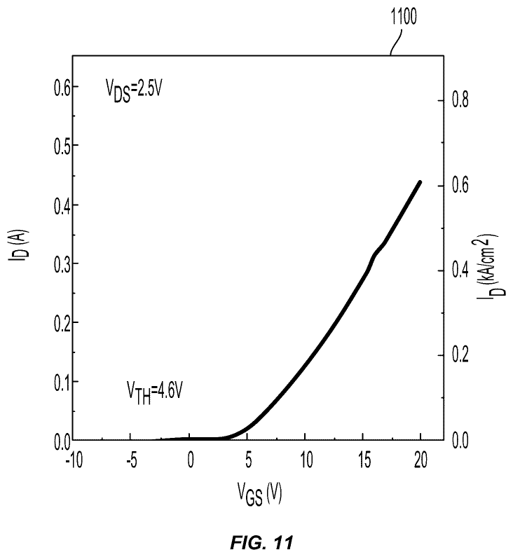

FIG. 11 is a graph 1100 illustrating the transfer characteristics of a large-area vertical transistor with a grooved gate according to some aspects of the present disclosure. In graph 1100, drain current Ip is plotted with respect to gate voltage V_{GS}, with V_{DS} at 2.5 V.

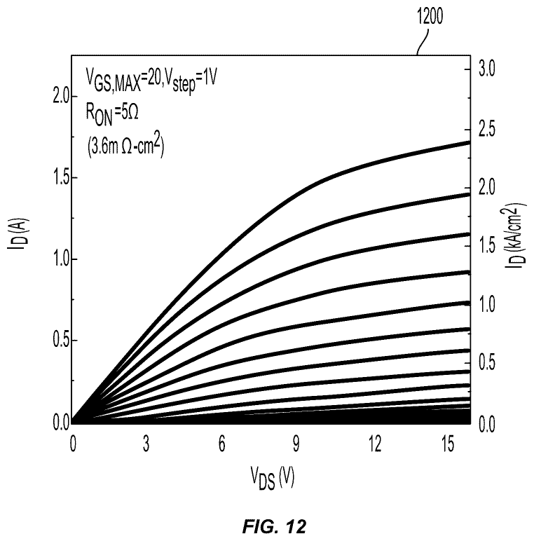

FIG. 12 is a graph 1200 illustrating the output characteristics of a large-area vertical transistor with a grooved gate according to some aspects of the present disclosure. The curves represent −1 V increments, showing drain current Ip with respect to drain source voltage VDS. A 20 V gate voltage swing is shown for the large-area device. As with the device with a single gate finger, the 20 V gate voltage swing is a limit of the test set up specific to the large area device tested, and is not necessarily a limit of the device. Practical devices with either the single-finger or multi-finger, large area configuration may achieve a gate swing voltage of up to 80 V, as previously stated, or up to the voltage at which the gate leakage current increases sharply (e.g., is comparable to the drain current level), which may ultimately cause the device to fail.

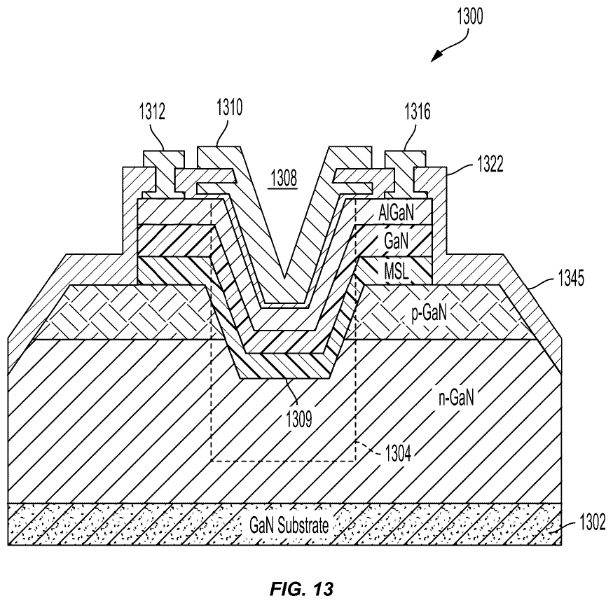

FIG. 13 is a cross-sectional view of a lateral transistor 1300 with a grooved gate according to additional aspects of the present disclosure. Transistor 1300 is a high-electron-mobility transistor (HEMT). Transistor 1300 includes a GaN substrate 1302 and grooves 1304, which are not directly visible in the cross-sectional view of FIG. 13. The grooves 1304 are defined substantially within trench 1308. Transistor 1300 also includes a stop layer 1306, gate 1310, source 1312, and drain 1316. The HEMT 1300 includes a dielectric insulating layer 1322 and a beveled edge 1345 as previously described with respect to the WG-CAVET shown in FIGS. 7A-7E.

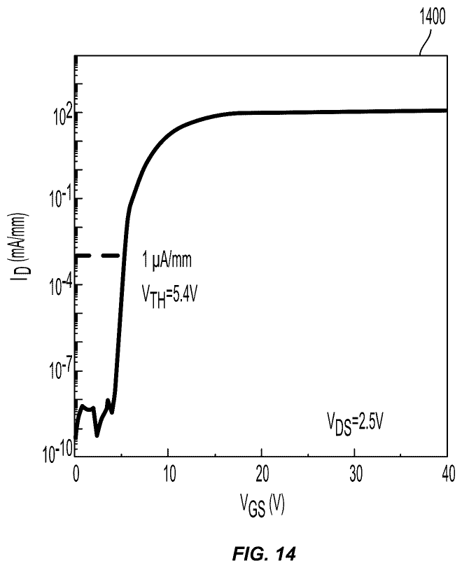

FIG. 14 is a graph 1400 illustrating the transfer characteristics of the HEMT 1300 according to additional aspects of the present disclosure. In graph 1400, drain current Ip is plotted with respect to gate voltage V_{GS}, with V_{DS} at 2.5 V.

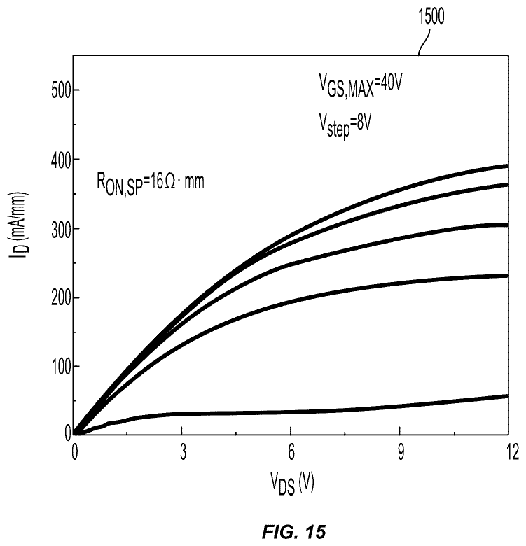

FIG. 15 is a graph 1500 illustrating the output characteristics of the HEMT 1300 according to additional aspects of the present disclosure. The curves represent-8 V increments, showing drain current Ip with respect to drain source voltage V_{DS}. The 40 V gate voltage swing for this HEMT was, as before, a limit of the equipment being used for testing, and is not necessarily a limit of the device.

The foregoing description of the examples, including illustrated examples, of the subject matter has been presented only for the purpose of illustration and description and is not intended to be exhaustive or to limit the subject matter to the precise forms disclosed. Directional references such as “vertical,” “on,” “covering,” “opposite,” “left,” and “right,” among others, are intended to refer to the relative orientation of a device and its components as illustrated and described in the figure (or figures) and are not intended to imply any particular configuration of a device in use or during manufacturing beyond that which may be expressly stated. Also, when a layer or feature is described as being “on,” “formed on,” “coupled with,” “coupled on,” or the like, with respect to another layer or feature, this description does not necessarily mean the two layers or features are in direct contact, as intervening layers or features may be present. The endpoints of numerical ranges recited herein include the concept of equality. Numerous modifications, adaptations, and uses thereof will be apparent to those skilled in the art without departing from the scope of this subject matter. The illustrative examples described above are given to introduce the reader to the general subject matter discussed here and are not intended to limit the scope of the disclosed concepts.

What is claimed is:

1. A trenched transistor comprising:
a substrate;
a p-n structure on the substrate, the p-n structure defining a trench;
channel material on at least a portion of the p-n structure opposite the substrate, the channel material covering the trench;
periodically-spaced grooves defined substantially within the trench, the periodically-spaced grooves penetrating at least a portion of the p-n structure;
an insulating layer on the channel material and on at least some internal surfaces of the periodically-spaced grooves; and
a gate on the insulating layer so as to incorporate the periodically-spaced grooves.

2. The trenched transistor of claim 1, further comprising a source electrode coupled with the channel material.

3. The trenched transistor of claim 2, wherein the gate comprises a plurality of fingers substantially coextensive with and wrapping around the source electrode, each of the plurality of fingers incorporating a plurality of the periodically-spaced grooves.

4. The trenched transistor of claim 1, wherein the p-n structure comprises p-GaN and n-GaN.

5. The trenched transistor of claim 1, wherein the channel material comprises unintentionally doped GaN.

6. The trenched transistor of claim 1, further comprising:
a stop layer between the channel material and the p-n structure; and
a barrier layer on the channel material configured so that a 2DEG channel forms in the channel material adjacent to a boundary between the channel material and the barrier layer.

7. The trenched transistor of claim 1, wherein each of the periodically-spaced grooves is oriented to be substantially perpendicular to a direction of the trench.

8. The trenched transistor of claim 1, wherein the periodically-spaced grooves are of a depth between 5 μm and 68 nm.

9. A current aperture vertical electron transistor (CAVET) comprising:
a GaN substrate;
a GaN p-n structure on the GaN substrate, the GaN p-n structure defining a trench;
a plurality of periodically-spaced grooves substantially within the trench and extending into the GaN p-n structure; and
a gate on the GaN p-n structure so as to incorporate the plurality of periodically-spaced grooves.

10. The CAVET of claim 9, further comprising:
unintentionally doped GaN (UID-GaN) channel material on the GaN p-n structure opposite the GaN substrate;
a source electrode coupled with the UID-GaN channel material; and
a drain electrode coupled with the GaN substrate.

11. The CAVET of claim 10, wherein the gate comprises a plurality of fingers substantially coextensive with and wrapping around the source electrode, each of the plurality of fingers incorporating a plurality of the periodically-spaced grooves.

12. The CAVET of claim 10, further comprising:
a stop layer between the UID-GaN channel material and the GaN p-n structure; and
a barrier layer on the UID-GaN channel material configured so that a 2DEG channel forms in the UID-GaN channel material adjacent to a boundary between the UID-GaN channel material and the barrier layer.

13. The CAVET of claim 9, wherein the periodically-spaced grooves have a width from 1.8 μm to 3.0 μm.

14. The CAVET of claim 9, wherein the periodically-spaced grooves extend to a depth between 5 μm and 68 nm.

15. The CAVET of claim 9, wherein the periodically-spaced grooves are spaced from 0.1 μm to 10 μm apart.

16. A method of making a vertical transistor, the method comprising:
etching a trench in a p-n structure;
regrowing channel material on the p-n structure to cover internal surfaces of the trench;
depositing a source electrode on the p-n structure and the channel material;
etching periodic grooves substantially within the trench and extending into the p-n structure; and
depositing a gate on at least some internal surfaces of the periodic grooves to form a grooved gate.

17. The method of claim 16, wherein the gate comprises a plurality of fingers substantially coextensive with and wrapping around the source electrode.

18. The method of claim 16, wherein the periodic grooves are etched to a depth between 5 μm and 68 nm, a width from 1.8 μm to 3.0 μm, and are spaced from 0.1 μm to 10 μm apart.

19. The method of claim 16, further comprising regrowing a barrier layer on the channel material.

20. The method of claim 19, wherein the channel material comprises unintentionally doped GaN, and the barrier layer comprises AlₓGa₍₁₋ₓ₎N.
